(19) United States
(12) Patent Application Publication
(10) Pub. No.: US 2009/0115525 A1
(43) Pub. Date: May 7, 2009

(54) FREQUENCY TUNABLE LOW NOISE AMPLIFIER

(75) Inventors: Seong-Mo Yim, Summerfield, NC (US); Kenneth Kyongyop O, Gainesville, FL (US)

Correspondence Address: AKERMAN SENTERFITT, P.O. BOX 3188, WEST PALM BEACH, FL, 33402-3188, US

(73) Assignee: University of Florida Research Foundation, Inc., Gainesville, FL (US)

(21) Appl. No.: 11/577,749

(22) PCT Filed: Oct. 21, 2005
(86) PCT No.: PCT/US05/37913

§ 371 Date: Apr. 23, 2007

Related U.S. Application Data
(60) Provisional application No. 60/621,550, filed on Oct. 22, 2004.

(51) Int. Cl. H03F 1/56; H03F 3/16

(52) U.S. Cl. 330/277; 330/302

(57) ABSTRACT

A frequency tunable low noise amplifier 100 providing multi-band operation includes an amplifier 110 and a frequency tunable input matching network 130 including at least one varactor 141, 142 coupled to an input of the amplifier 110. The input network receives a signal from a signal source 160. The input matching network 130 includes a control input 171 for providing an impedance match to the source 160. A frequency tunable output matching network 140 includes at least one varactor 181, 182 coupled to an output of the amplifier 110. The output matching network 140 also includes a control input 191 for providing an impedance match to a load 195.

### FIELD OF THE INVENTION

The invention relates analog circuits and more specifically to analog circuits which provide tunable operating frequencies.

### BACKGROUND

A wide variety of communication applications using numerous frequency bands and standards such as the global system for mobile communication (GSM, RX 935-960 MHz, TX 890-915 MHz)), digital cellular system (DCS1800, RX 1805-1880 MHz, TX 1710-1785 MHz), personal communication system (PCS, RX 1930-1990, TX 1850-1910 MHz), wide-band CDMA (RX 2110-2170, TX 1920-1980 MHz), global positioning system (GPS, 1.275 & 1.57 GHz), Wireless LAN (2.4, 4.9.5.2. and 5.8 GHz), and Bluetooth (2.4 GHz) have emerged. For seamless communication at any time and any place, these systems are required to coexist, and the demands for radios which can handle many if not all of these applications/systems axe expected to rapidly increase. This type of demand is traditionally addressed by having multiple sets of key RF blocks, which each handle one of the bands.

However, the multiple RF block approach increases the die area or number of integrated circuits and thus increases the cost and reduces the reliability as compared to a radio having a single RF block. Accordingly, a radio design is needed for multi-band operation having a single RF block to reduce the die area and IC count as compared to conventional multi-band radio designs.

### SUMMARY

A frequency tunable low noise amplifier (LNA) providing multi-band operation includes an amplifier, and a frequency tunable input matching network including at least one varactor coupled to an input of the amplifier. The input network receives a signal from a signal source. The input matching network includes a control input for providing an impedance match to the source. A frequency tunable output matching network includes at least one varactor coupled to an output of the amplifier. The output matching network also includes a control input for providing an impedance match to a load.

The varactors are preferably on-chip varactors. At least one of the varactors comprise source/drain to gate capacitive switches. in a preferred embodiment, the varactors are back-to-back accumulation mode MOS structures disposed in a common well, wherein gates of the MOS structures are connected to an RF input provided by the signal source, with the well being connected to a control voltage. The varactors can provide a maximum to minimum capacitance ratio of at least 4.

The input network generally comprises at least one inductor, the inductor causing an input impedance of the input network for two spaced apart frequency bands to converge to an output impedance of the signal source. The output network can include at least one capacitive switch. The capacitive switch can include a control input, where the control input changes a capacitance of the switch. The output network can be entirely on-chip.

The LNA provides an impedance match over at least 2 spaced apart RF bands. The center frequency of the RF bands can be spaced apart by at least one octave, or more. The LNA can further comprise an inductor in the input network in series with the amplifier, wherein the inductor compensates for a parasitic capacitance of the varactor in the input network.

### BRIEF DESCRIPTION OF THE DRAWINGS

A fuller understanding of the present invention and table features and benefits hereof will be accomplished upon review of the following detailed description together with the accompanying drawings, in which:

FIG. 1 is a schematic showing a circuit comprising a frequency tunable low noise amplifier (LNA) having frequency tunable input and output impedance matching network, according to an embodiment of the invention.

FIG. 2 shows a plot of the input reflection coefficient (S₁₁) evidencing input matching for the circuit shown in FIG. 1 as a function of frequency (in GHz) as the varactor capacitance (C_{Vin}) in the input network is varied from 2 to 4 pF.

FIGS. 3(a)-(d) shows variable input matching S₁₁ of the circuit shown in FIG. 1 using on-chip varactors (C_{Vin}) and its parasitic capacitance (C_{Par}) at various frequencies and varactor capacitances.

FIG. 4(a) shows L-C components used in the input network and FIGS. 4(b) and (c) shows their effect on tuning bandwidth.

FIG. 5 is a plot of capacitance and Q factor vs. gate voltage for an exemplary NMOS capacitive switch.

FIG. 6 shows the measured output reflection coefficient |S22|. As CVload and CVout are increased, the output network can be tuned at frequencies between ˜0.7 and ˜2.2 GHz.

FIGS. 7(a) and (b) shows the various S-parameters as a function of frequency.

### DETAILED DESCRIPTION

A frequency tunable low noise amplifier circuit providing multi-band operation includes an amplifier, and a frequency tunable input matching network including at least one varactor coupled to an input of the amplifier. The input network receives a signal from a signal source. The input matching network includes a control input for providing an impedance match to the source. A frequency tunable output matching network includes at least one varactor coupled to an output of the amplifier. The output matching network also includes a control input for providing an impedance match to a load.

The invention is described relative to an exemplary single RF front end low noise amplifier (LNA) which was designed, fabricated in a 0.18-μm CMOS process, and tested which demonstrated tuneability between about 0.7 and 1 GHz and between about 1.5 and 2.0 GHz, such as for RF band operation near 0.9, 1.57, 1.8 and 1.9 GHz. As will be evident based on the description below, the invention is clearly not limited to the specific process used, the specific design used, the particular bands handled, nor the number of bands obtained.

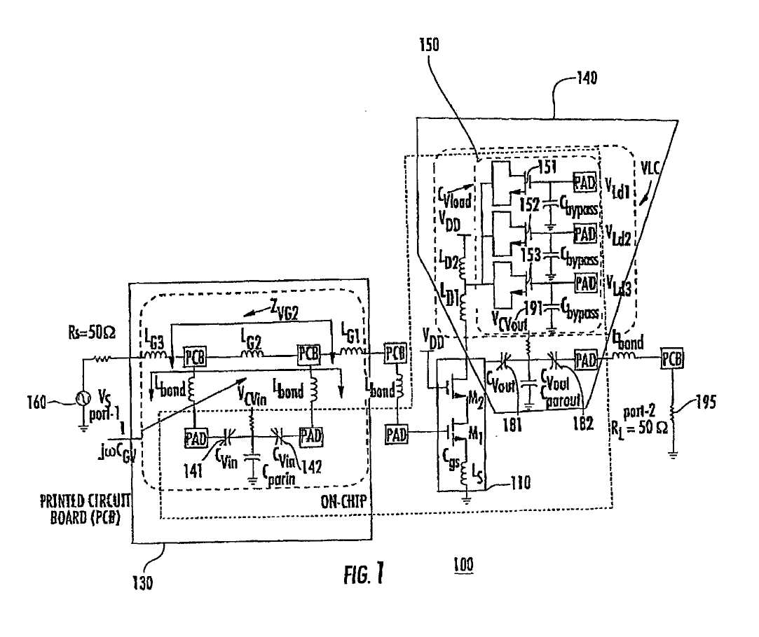

FIG. 1 shows a frequency tunable LNA 100 according to an exemplary embodiment of the invention. LNA 100 includes a cascode amplifier 110 having inductive source degeneration (Ls) to generate positive resistance looking into the gate of common source transistor M₁, frequency tunable input network 130 and output network 140 each matched to a 50Ω load 195. To the first order, the resistance looking into the gate of M₁ is independent of frequency. Although amplifier 110 is shown as a cascode amplifier in FIG. 1, the invention is in no way limited to cascode amplifiers, nor MOS devices, nor single stage amplifiers.

The tunable input matching network 130 includes of three off-chip inductors L_{G1-3}, three bond-wire/lead inductors (L_{Bond}), and two (2) on-chip varactors (C_{Vin}). On chip components are shown within the dotted line shown, while off chip components are shown outside the dotted line for the prototype radio designed and fabricated. Although LNA 100 shown in FIG. 1 includes off-chip components comprising inductors L_{G1-3}, LNA 100 can be embodied using all integrated components.

The input matching network 130 which includes varactors 141 and 142 is tuned by changing the varactor capacitance (C_{Vin}) through application of control voltage V_{CVin} 171. The tunable output matching network 140 is fully integrated on-chip, and includes a capacitively switched variable L-C tank (VLC) 150 and two varactors (C_{Vout}) 181,182. The varactor capacitance of C_{Vout} is controlled by application of control voltage V_{CVout} 191. The output network 140 is tuned by changing the parasitic capacitance of L_{D1} and L_{D2}, the C of VLC 150, and the varactor capacitances (C_{Vout}) though application of the control voltage V_{CVout} 191.

There are generally significant parasitic effects on input matching. When a VLC or a varactor is used for input matching, such as in input matching network 130 and the output matching network 140 in LNA 100 shown in FIG. 1, such structures preferably have low series resistance and parasitic capacitance to prevent increases of noise figure (NF), while maintaining 50-Ω matching (or other desired impedance level). On-chip capacitors and varactors with high Q at 1-5 GHz are acceptable for this purpose. On the other hand, integrated VLC's using a transistor switch are generally avoided because their losses can significantly degrade the NF.

The series resistance of the on-chip varactors can be made negligible by using a moderate valued high Q varactor. However, increasing the varactor value increases parasitic capacitance and the loss through substrate. The loss through substrate can decrease power gain and input impedance, and increase the NF. The parasitic capacitance of varactors (C_{Parin}) in FIG. 1 also complicates input matching. As a result, the network is no longer a simple series network. As the frequency increases, the real part of the input impedance is decreased by C_{Parin} which makes input matching difficult over a wide frequency range. Therefore, it is generally important to minimize C_{Parin}.

If C_{Parin}, L_{G3} and L_{bond}'s are excluded and the varactor C_{Vin}, is modeled as a capacitor, then the resulting circuit is the same as an input matching network having two resonances. Accordingly, matching network 130 shown in FIG. 1 is expected to have multiple frequencies when the input from signal source 160 is matched to 50Ω (or other impedance level). As will be described below, L_{G1} enables matching by compensating for the presence of C_{Parin}.

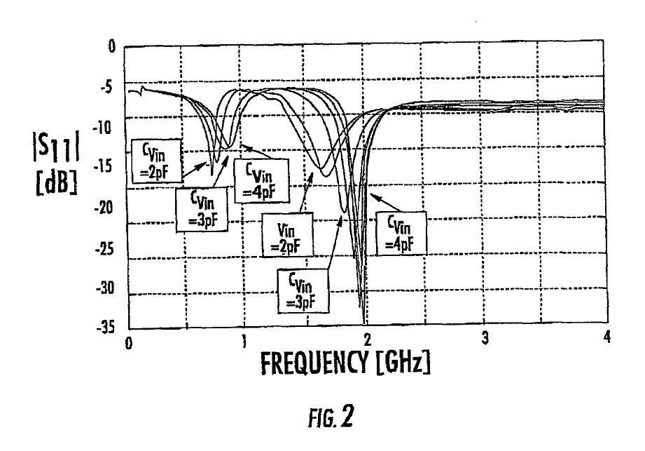

FIG. 2 shows a plot of input reflection coefficient (S₁₁) for the circuit shown in FIG. 1 as a function of frequency (in GHz) as the varactor capacitance (C_{Vin}) in the input network is varied from 2 to 4 pF. When the varactor control voltage (V_{CVin}) in FIG. 1 is 0 V, Cᵥᵢₙ is −2 pF, and the measured |S₁₁|'s are −13.4 dB at 0.73 GHz and −12.3 dB at 1.62 GHz. As the control voltage V_{CVin}, increases, the capacitance (Cᵥᵢₙ) increases and the measured frequency bands matched to 50Ω shift up in frequency as shown in FIG. 2. For example, when V_{CVin} is 1.8V, C_{Vin} is ˜4 pF, and measured |S₁₁|'s are −9.4 dB at 0.91 GHz and less than −10 dB at 1.98 GHz. Thus, the impedance of the input network 130 can concurrently be matched to 50Ω from 0.7 to 1.0 GHz and from ˜1.5 to ˜2.1 GHz by controlling input V_{CVin} from 0 to 1.8 V.

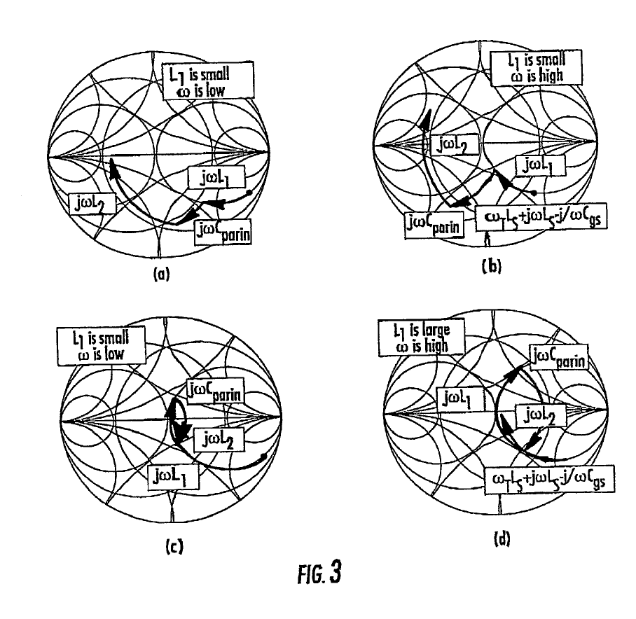

The varactors C_{Vin} are preferably implemented using two integrated back-to-back accumulation mode MOS structures in a shared n-well to reduce Cₚₐᵣᵢₙ. The gates of the MOS structures M₁ and M₂ are connected to the RF source (V_{S}) 160 and the shared n-well is connected to the control (V_{CVin}) 141. The parasitic capacitance Cₚₐᵣᵢₙ of the varactors Cᵥᵢₙ de-tunes the input matching network 130 at both 0.91 and 1.98 GHz. However, by including the inductor L_{G1} and properly selecting its value, Cₚₐᵣᵢₙ can make the input impedance to move around the 50-Ω point and the impedances at the two bands to converge to 50Ω. FIGS. 3(a)-(d) demonstrates variable input matching S₁₁ of the circuit shown in FIG. 1 using on-chip varactors (C_{Vin}) 141 and 142 and its parasitic capacitance (C_{Par}) at various frequencies and varactor capacitances.

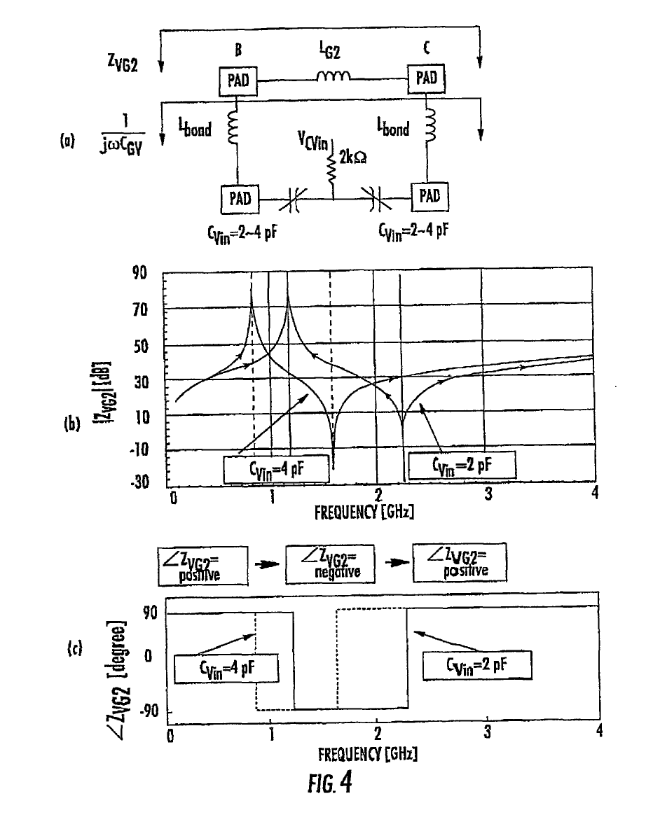

In FIG. 1, neglecting Cₚₐᵣᵢₙ, L_{bond}'s and C_{Vin}'s forms a series resonant circuit and results in a zero at a resonant frequency around 2 GHz. These elements and an off-chip inductor, L_{G2} form a parallel resonant circuit and result in a pole around 1 GHz. The impedance (Z_{VG2}) shown in input network 130 in FIG. 1 less Cₚₐᵣᵢₙ is shown in FIG. 4(a), and is given by:

$${Z}_{VG 2} = j ω {L}_{G 2} - \frac{1 - {ω}^{2} {L}_{bond} {C}_{Vin}}{1 - {ω}^{2} ( \frac{1}{2} {L}_{G 2} + {L}_{bond}^{-} ) {C}_{Vin}} \qquad ( 1 )$$

Since the off-chip inductor L_{G2} and varactors C_{Vin} have high Q factors and the combination has one pole and one zero at

$$\frac{1}{\sqrt{( 0.5 {L}_{G 2} + {L}_{bond} ) {C}_{Vin}}} and \frac{1}{\sqrt{{L}_{bond} {C}_{Vin}}} ,$$

respectively, Z_{VG2} is greatly influenced by C_{Vin} (FIG. 4(b)). Depending on frequency, Z_{VG2} can be made to be inductive (up to about 1.2 GHz, and >2.3 GHz) and capacitive between about 1.2 GHz, and 2.3 GHz as shown in FIG. 4(c). These characteristics provide flexibility to tune the input network 130 over a wide frequency range.

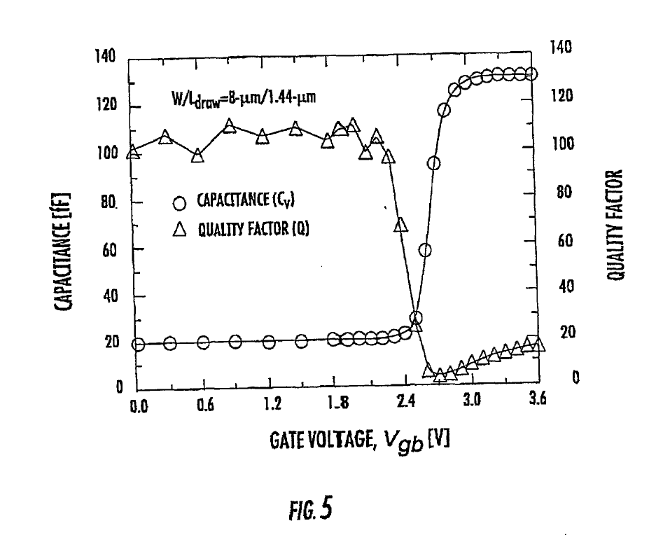

Output matching is provided in LNA 100 using an output matching network 140 comprising a variable L-C tank 150. The output matching network 140 shown in FIG. 1 is essentially an L-matching network composed of a shunt inductor, L_{D}, and a series capacitor formed with two series Cᵥₒᵤₜ's. L_{D}, parasitic capacitance of L_{D}. The capacitance of varactors Cᵥₒᵤₜ are varied to frequency tune the output network 140 while keeping Q thus gain relatively constant. L_{D} and its parasitic capacitance are varied using NMOS source/drain to gate capacitive switches 151-153 shown in FIG. 1. By varying the capacitance seen from the source/drain node to gate, the capacitance of capacitive switches 151-153 can be changed between the full gate oxide capacitance and the capacitance associated with the gate to drain/source overlap capacitance and drain/source to substrate junction capacitances to achieve a maximum to minimum capacitance ratio of 6.8 as shown in FIG. 5. The quality factor at 2 GHz when the switch 151-153 is on or the capacitance is high, Qₒₙ is about 8. By controlling the three capacitive switches 151-153 shown in FIG. 1 with three control pins, V_{Ld1}, V_{Ld2}, and V_{Ld3}, C_{Vload} in FIG. 1 can be set to about 2.3, 5.7, 9.0, 12.4 and 15.7 pF, which in turn simultaneously varies the inductance and capacitance seen from the drain node of M₂. The series C of the output network 140 is formed with two integrated back-to-back accumulated-mode varactors (C_{Vout}). The total series capacitance can be changed from 4 to 8 pF by varying the control voltage V_{CVout} 191.

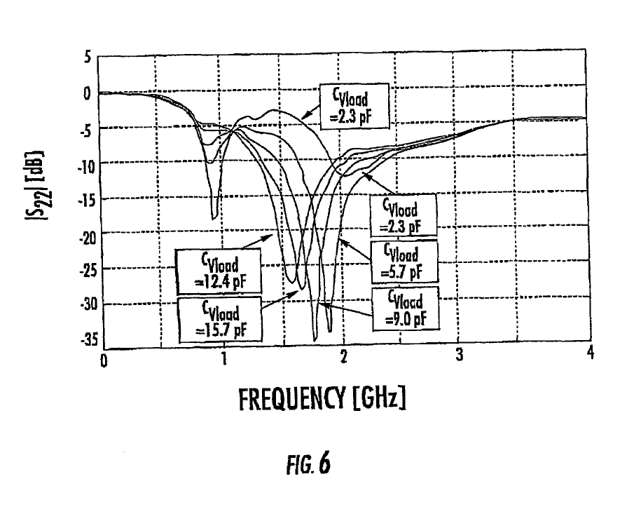

FIG. 6 shows the measured output reflection coefficient |S22|. As CVload and CVout are increased, the output network can be tuned at frequencies between ˜0.7 and ˜2.2 GHz.

Regarding noise performance of LNA 100, for cascode CMOS LNAs with inductive source degeneration there is an optimum Q_{Vgs} at which noise factor is the minimum. Q_{Vgs} is given by:

$$\frac{1}{{ω}_{0} {C}_{i n} ( {ω}_{T} \cdot {L}_{s} )} = \frac{1}{{ω}_{0} {C}_{i n} 50} \qquad ( 2 )$$

where Cᵢₙ is the total input capacitance. This optimum Q_{Vgs} is independent of operating frequency. As illustrated in FIG. 4(c), if Cₚₐᵣᵢₙ is neglected, then Z_{VG2} starts inductive and becomes capacitive as frequency is increased to about 1.2 GHz. Cᵢₙ is the effective capacitance of Z_{VG2}+1/jωC_{gs}, which is approximately C_{gs} at ˜0.8 GHz and ˜0.75 C_{gs} near 1.8 GHz. To maintain relatively constant Q_{vgs}, or to keep the noise matching optimum over the frequency range, the effective capacitance associated with Z_{VG2}+1/jωCgs should be reduced with frequency and this effect can be partially achieved by using the frequency dependence of Z_{VG2} shown in FIG. 4(b). When the frequency is further increased to about 2.2 GHz, Z_{VG2} acts as an inductor which increases Q_{Vgs}. This problem, however, can be solved by changing C_{Vin} to 2 pF by changing V_{CVin} which makes Z_{VG2} once again acting like a series capacitor to achieve relatively constant Q_{Vgs} over frequency.

The invention thus provides reconfigurable RF circuits with dynamically tunable operating frequencies utilizing a combination of multiple resonant networks and frequency tuning to realize multi-band operation using a single RF front end. The input and output matching networks permit turning over a large frequency range and also provide near optimal noise matching over the frequency range. The die size of multi-band low noise amplifiers (LNAs) according to the invention are considerably smaller than convention multi-band designs which require separate LNAs for each desired band, such as less than ½ the size of a conventional four (4) band amplifier.

The frequency tuning designs and techniques described herein according to the invention is expected to have a wide variety of applications. For example, the invention can be used in intelligent communication systems that can dynamically adjust spectrum usage. In addition, the invention can be used to tune circuits post wafer processing to compensate for process variations and operate tuned circuits with higher Q for lower power consumption. The invention can thus significantly benefit communications, computing and telecommunications applications and devices such as cell phones, personal digital assistants (PDA's) and laptops with enhanced communication capability.

### EXAMPLES

The present invention is further illustrated by the following specific examples, which should not be construed as limiting the scope or content of the invention in any way.

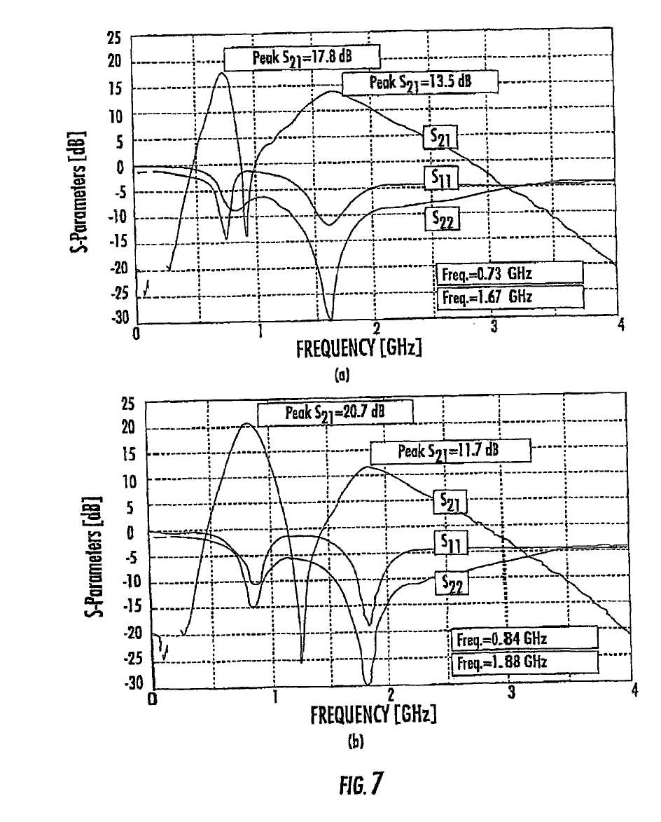

LNA 100 shown in FIG. 1 was fabricated as noted above using a 0.18-μm CMOS process, and the resulting LNA 100 tested. FIGS. 7(a) and (b) shows plots of measured |S₂₁| versus frequency for LNA 100. The LNA evidenced two tuned frequencies. The tuned frequencies for the plots are 0.73/1.67 GHz (FIG. 7(a)) and 0.84/1.88 GHz (FIG. 7(b)). The peak gain |S₂₁|'s are nicely aligned with the minimums of input reflection coefficient |S₁₁| and input reflection coefficient |S₂₂|. By controlling input and output accumulation-mode varactors using a control voltages V_{CVin} and V_{CVout}, respectively, and NMOS source/drain to gate capacitive switches 151-153 using control voltage V_{Ld1-3}, the matching frequency for input network 130 and output network 140 is varied from 0.73 to 0.91 GHz. and from 1.64 to 1.98 GHz.

In the 0.73-0.91 GHz range the LNA provided a maximum |S₂₁| of 23.0 dB, and the minimum NF of 1.32 dB at 0.77 GHz. IP_{1dB} was measured at about −15 dBm. IIP₃ was measured at about −8 dBm. In the 1.69-1.98 GHz range the maximum |S₂₁| was measured as 15.3 dB. The NF was measured at 2.54 dB at 1.69 GHz, 2.94 dB at 1.81 GHz, and 3.93 dB at 2.1 GHz. IP_{1dB} was measured at about −8 to −9 dBm. IIP₃ was measured at about −0.5 dBm.

The die size of the tunable LNA 100 was 570×850 μm² excluding the pads. The size of the multi-band single band LNA die was estimated to be about 0.28 mm². The die size of the multi-band LNA should be ˜14%, ˜43%, and ˜57% smaller than conventional radio designs having two, three, and four single band LNA's, respectively. The performance of the tunable LNA is summarized in Table I below.

TABLE I

| Frequency | | N.F. | \|S₂₁\| [dB] | IIP₃ [dBm] |
|---|---|---|---|---|
| 0.72 | GHz | 1.74 | 20.7 | −3.17 |
| 0.72/1.69 | GHz | 1.83/2.54 | 17.8/13.5 | −6.5/+2.33 |
| 0.76/1.74 | GHz | 1.54/2.77 | 17.5/14.0 | N/A |
| 0.81 | GHz | 1.74 | 22.0 | −3.08 |
| 0.84/1.88 | GHz | 1.32/2.94 | 20.7/11.7 | −6.17/+8.42 |
| 0.90/2.05 | GHz | 1.49/3.93 | 23.0/11.2 | −2.25/+4.50 |

This invention can be embodied in other forms without departing from the spirit or essential attributes thereof. Accordingly, reference should be made to the following claims, rather than to the foregoing specification, as indicating the scope of the invention.

We claim:

1. A frequency tunable low noise amplifier (LNA), comprising:
an amplifier;
a frequency tunable input matching network including at least one varactor coupled to an input of said amplifier, said input network for receiving a signal from a signal source, said input matching network including a control input for providing a tunable impedance match to said source, and
a frequency tunable output matching network including at least one varactor coupled to an output of said amplifier, said amplifier driving a load, said output matching network including a control input for providing a tunable impedance match to said load.

2. The LNA of claim 1, wherein said varactors are on-chip varactors.

3. The LNA of claim 1, wherein at least one of said varactors comprise source/drain to gate capacitive switches.

4. The LNA of claim 1, wherein said varactors are back-to-back accumulation mode MOS structures disposed in a common well, wherein gates of said MOS structures are connected to an RF input provided by said signal source, said well being connected to a control voltage.

5. The LNA of claim 1, wherein said varactors provide a maximum to minimum capacitance ratio of at least 4.

6. The LNA of claim 1, wherein said input network comprises at least one inductor, said inductor causing an input impedance of said input network for two spaced apart frequency bands to converge to an output impedance of said signal source.

7. The LNA of claim 1, wherein said output network includes at least one capacitive switch.

8. The LNA of claim 7, wherein said capacitive switch includes a control input, said control input changing a capacitance of said switch.

9. The LNA of claim 1, wherein said output network is entirely on-chip.

10. The LNA of claim 1, wherein said LNA provides said impedance match over at least 2 spaced apart RF bands.

11. The LNA of claim 1, wherein a center frequency said RF bands are spaced apart by at least one octave.

12. The LNA of claim 1, further comprising an inductor in said input network in series with said amplifier, said inductor compensating for a parasitic capacitance of said varactor in said input network.
